(19) United States
(12) Patent Application Publication
(10) Pub. No.: US 2025/0391796 A1
(43) Pub. Date: Dec. 25, 2025

(54) ELECTRONIC DEVICE OPTIMISED LARGE AREA INTERCONNECTION

(71) Applicant: RAM Innovations Ltd, Pentre (GB)

(72) Inventor: Andrew ROBERTS, Pentre (GB)

(21) Appl. No.: 19/213,526

(22) Filed: May 20, 2025

(30) Foreign Application Priority Data
Jun. 20, 2024 (GB) GB2408871.8

(51) Int. Cl. H01L 23/00; H01L 23/538

(52) U.S. Cl. CPC H01L 24/19; H01L 23/5386; H01L 23/5389; H01L 24/20; H01L 2224/2101; H01L 2224/2105; H01L 2224/215; H01L 2924/01029; H01L 2924/10272; H01L 2924/1033

(57) ABSTRACT

A method for manufacturing an embedded die electronic device. The method provides an embedded die substrate having a dielectric layer and a die at least partially embedded within the dielectric layer. The die has a die substrate and at least one die contact pad atop the die substrate. The die contact pad has a top surface having a first footprint. The method also removes a portion of the dielectric layer to create an opening down to the top surface of the die contact pad. The opening has a second footprint in a plane defined by the top surface of the die contact pad. The second footprint matches the first footprint. The method forms one or more tracks on the embedded die substrate. Forming the one or more tracks comprises filling in the opening with a conductive material.

### FIELD OF THE INVENTION

The present invention relates to the manufacture of embedded electronic devices. More specifically, but without limitation, the present invention relates to the manufacture of embedded die power electronic devices.

### BACKGROUND TO THE INVENTION

Embedded electronic device packaging is one way of forming a complex power module, power conversion sub-system or other electrical systems. There are many advantages to embedded electronic device packaging, including increased miniaturisation, more reliable interconnection, better electrical and thermal performance and better protection for integrated components.

At the core of most modern-day electronics are semiconductor devices and other Integrated Circuits (IC's) as well as other electrical components. In the context of this patent application, we shall call them all a “die” throughout this document. High-performance dies, exhibit remarkable capabilities but are also prone to generating excessive heat during operation, however it should be noted that other electrical components can also produce heat during operation. In instances wherein a die is encapsulated within a surrounding dielectric material having a relatively low thermal conductivity, heat dissipation from the die may be reduced by the surrounding encapsulant.

Recently, Wide Band Gap (WBG) semiconductor devices or “Dies” have been heralded as pivotal components in the future landscape of power electronics, offering the promise of elevated power density at a reduced system cost. However, the packaging of these devices has emerged as a critical bottleneck in fully harnessing their potential. To optimize their fast-switching capabilities, effective thermal management is imperative, particularly due to their compact size and high losses level. Fundamentally, efficient heat dissipation is crucial for ensuring optimal performance and longevity of these semiconductor dies.

During a conventional chip or die embedding processes, a die is embedded in a substrate, wherein the substrate comprises a top layer of copper and an underlying layer of dielectric. Subsequently, mainstream Printed Circuit Board (PCB) manufacturing style vias or micro-vias (either singly or jointly) are drilled through the copper layer and the dielectric layer to make vertical connections from the underlying die contacts to overlying circuitry within the device being manufactured. While this approach facilitates electrical connectivity, it introduces a matrix of electrically and thermally insulating material within areas that would benefit from uninterrupted connections. This configuration creates thermal bottlenecks, limiting the effective dissipation of heat from the die. As a result, elevated temperatures may compromise device performance and reliability. Therefore, innovative techniques are urgently needed to enhance heat dissipation and address the limitations of conventional embedded die manufacturing processes.

Embodiments of the present invention seek to overcome these or other disadvantages and to provide an improved method of manufacture of an embedded die electronic device

### SUMMARY OF THE INVENTION

According to a first aspect of the present invention there is provided a method of manufacturing an embedded electronic device. The method may comprise providing an embedded die substrate. The embedded die substrate may comprise a dielectric layer and a die may be at least partially embedded within the dielectric layer. The die may comprise a die substrate and at least one die contact pad atop the die substrate. The die contact pad may comprise a top surface having a first footprint. The method may further comprise removing a portion of the dielectric layer to create an opening down to the top surface of the die contact pad. The opening may comprise a second footprint in a plane defined by the top surface of the die contact pad. The second footprint may substantially match the first footprint. The method may further comprise forming one or more tracks on the embedded die substrate. Forming the one or more tracks on the embedded die substrate may comprise filling in the opening with a conductive material.

In some embodiments, the embedded electronic device may comprise an embedded die power electronic device. Additionally, the die substrate may comprise a semiconductor die substrate. The die may comprise a semiconductor die. The contact pad may comprise a semiconductor contact pad.

The second footprint may substantially match the first footprint if the size of a surface area covered by the second footprint is identical or substantially similar to the size of the surface area covered by the first footprint. In some embodiments, the opening down to the top surface of the die contact pad may expose at least 60%, 70%, 80%, 90%, 95%, 98% or 99% of the top surface of the die contact pad. The size of the surface area covered by the second footprint may be at least 60%, 70%, 80%, 90%, 95%, 98% or 99% of the size of the surface area covered by the first footprint.

In some embodiments there may be a continuous 20 μm-100 μm separation between an outer edge of the second footprint and an outer edge of the first footprint. The at least one die contact pad may comprise 20 μm-100 μm of radial land around the opening in a plane defined by the top surface of the die contact pad. More preferably, there may be a continuous 25 μm-60 μm separation between an outer edge of the second footprint and an outer edge of the first footprint. In other words, the at least one die contact pad may comprise 25 μm-60 μm of radial land around the opening in a plane defined by the top surface of the die contact pad. More preferably, there may be a continuous 30 μm-50 μm separation between an outer edge of the second footprint and an outer edge of the first footprint. These specific values of the radial land expose a sufficient amount of the contact pad to ensure an optimal conductive material fill, thereby enhancing the thermal and electrical connectivity between the die and any circuitry atop the embedded die substrate. At the same time this separation ensures that any electrical connection stays within the confines of the contact pad and prevents shorts.

Additionally or alternatively, the second footprint may substantially match the first footprint if a shape of the second footprint is identical or substantially similar to a shape of the first footprint. For example, the second footprint may be geometrically similar to the first footprint.

The exact size and/or shape of the second footprint and/or the size of the radial land around the opening may be determined when designing a specific embedded electronic device. This is because, each embedded electronic device may have its own technical requirements when it comes to the current carrying cross section of the electrical connections and/or the required area for conducting/spreading heat from the die substrate.

The disclosed method of manufacturing an embedded electronic device offers significant improvements over the existing manufacturing techniques by addressing key limitations in thermal management and manufacturing efficiency for embedded electronic devices. By creating an opening in the dielectric layer that matches the footprint of the die contact pad, the method ensures optimal conductive material fill, thereby enhancing the thermal and electrical connectivity between the die and any circuitry atop the embedded die substrate. Advantageously, the claimed method reduces thermal resistance, facilitating more efficient heat dissipation from the die.

The dielectric layer may cover the entire top surface of the die. The dielectric layer may cover the entire top surface of the at least one die contact pad atop the die substrate. In this configuration, at least a portion of the dielectric layer may need to be removed during the manufacturing process to expose the whole or a part of the top surface of the at least one die contact pad.

The die contact pad may comprise a conductive material. The die contact pad may comprise copper or other conductive material.

The dielectric layer may comprise an epoxy resin. More specifically, the dielectric layer may comprise a tetrafunctional epoxy resin. In some embodiments, the dielectric layer may comprise Bismaleimide resin, Triazene resin and/or Polyimide resin or other insulative materials. The dielectric layer may comprise a Resin Coated Copper foil. A skilled person would recognise that various types of resin may be used to form a part or the whole of the dielectric layer. Additionally, a various additives or filler may be added to a given resin to give greater stability of the dielectric layer at a specific operating temperature, or to enhance electronic properties such as propagation delay or dielectric withstand of the embedded die electronic device.

The method for manufacturing an embedded die electronic device may further include a step of cleaning the top surface of the die contact pad. This step may be executed after a portion of the dielectric layer has been removed to create an opening down to the top surface of the die contact pad and before the one or more tracks are formed on the embedded die substrate.

Cleaning the top surface of the die contact pad may comprise applying an alkali solvent to the top surface of the die contact pad. Advantageously, by applying the alkali solvent to the top surface of the die contact pad any remaining resin smear or particles covering the contact pad are softened. Subsequently, an alkali permanganate may be applied to the top surface of the die contact pad. Advantageously, by applying the alkali permanganate to the top surface of the die contact pad, any remaining resin smear or particles are removed, and any retained dielectric surfaces are roughed to ensure a good adhesion of the conductive material.

Additionally or alternatively, cleaning the top surface of the die contact pad may comprise applying hydrofluoric acid to the top surface of the die contact pad. This cleaning method may be especially effective when a large amount of leftover dielectric material is evident.

Advantageously the cleaning step is configured to remove any leftover dielectric material from the top surface of the die contact pad. It is essential that any resin smear or particles are removed, otherwise the conductive material deposited during a metallisation process will form over those deposits, causing a weak joint between the conductive material and the contact pad. This weak joint may be likely to fracture, resulting in a damaged embedded die electronic device.

Forming one or more tracks on the embedded die substrate may comprise forming one or more tracks on a top surface of the embedded die substrate. More specifically, forming one or more tracks on the embedded die substrate may comprise forming one or more tracks on a top surface of the dielectric layer. The one or more the tracks may connect to the exposed parts of the die. The one or more the tracks may connect to the one or more die contact pads. The one or more the tracks may connect to the die contact pad through the opening. The one or more the tracks may comprise an electrical connection to the one or more die contact pads. The electrical connection between the one or more tracks and the one or more die contact pads may be facilitated by the opening filled in with the conductive material.

The one or more tracks may comprise a conductive material. The conductive material may comprise copper. In some embodiments, the conductive material may comprise silver. Similarly, the conductive material used to fill in the opening may comprise copper and/or silver. Filling in the opening with the conductive material may comprise copper metallisation. The conductive material may comprise a thermally and electrically conductive material.

The skilled person would recognise that forming the one or more tracks on the embedded die substrate may be realised in different ways. For example, the one or more tracks may be formed using a standard photolithography resist patterning followed by an acid spray etching. The skilled person would recognise that there exist many other methods of forming the one or more tracks on the embedded die substrate.

The opening down to the top surface of the die contact pad may not comprise a via. The opening down to the top surface of the die contact pad may not comprise a micro-via. The process of removing a portion of the dielectric layer to create an opening down to the top surface of the die contact pad may not comprise creating one or more vias and/or one or more micro-vias.

The opening down to the top surface of the die contact pad may not comprise a cylinder. The opening down to the top surface of the die contact pad may not comprise a conical frustum. The process of removing a portion of the dielectric layer to create an opening down to the top surface of the die contact pad may not comprise creating or drilling a cylinder and/or a conical frustum. The second footprint may not comprise a circular or elliptical surface-area. The first footprint may not comprise a circular or elliptical surface area.

A via may comprise a drilled hole having a substantially circular cross-section. The via may comprise a diameter of 0.2-0.5 mm. Some vias may comprise a diameter of up to 1 mm. According to an accepted definition within IPC-T-50M a micro-via is a blind structure with a maximum aspect ratio of 1:1, terminating on a target land with a total depth of no more than 0.25 mm measured from the structure's capture land foil to the target land. Micro-vias may comprise a diameter of less than 150 μm. Preferably micro-vias may comprise a diameter of 50-100 μm.

The present invention addresses the limitations of current manufacturing processes, which typically utilize conventional Printed Circuit Board (PCB) manufacturing style micro-vias. These micro-vias, arranged singly or in grid arrays, create vertical connections from the one or more die contact pads to the overlying tracks within the device. However, this method is suboptimal because it leaves a matrix of electrically and thermally insulating material within areas that would benefit from uninterrupted connections. By precisely removing portions of the dielectric layer to create openings that match the footprint of the one or more die contact pads, and subsequently filling these openings with conductive material, the disclosed method ensures optimal electrical and thermal connectivity.

Some experimental manufacturing techniques involve increasing the micro-via density to provide an improved thermal connection in a multilayer structure of a PCB. This approach involves drilling and plating a first set of micro-vias and subsequently placing a second set of micro-vias in the unplated regions between the already established micro-vias. This approach is unsatisfactory and impractical.

Firstly, the production of micro-vias is time-consuming, particularly when using CNC drilling machines. The requirement to drill multiple sets of vias sequentially creates a significant bottleneck in packaging or PCB manufacturing facilities. Additionally, ensuring clean via sidewalls while removing the dielectric without damaging the die or surrounding components is highly challenging and increases the likelihood of catastrophic failures. The repeated drilling of micro-vias increases the risk that a high-powered laser is left on for slightly too long thereby damaging the die. Lastly, the overlapping grids of micro-vias would need to remove all of the dielectric material from the opening between the underlying die contact pads and the overlying tracks. This is because any remaining dielectric would likely cause delamination and/or fatigue stress of the electrical connection between the one or more contact pads and the overlying tracks. It is extremely difficult, if not impossible, to fully remove the dielectric material from the opening by drilling multiple micro-via arrays. Fundamentally, this experimental method leads to a production of unreliable embedded die electronic devices that are prone to damage.

In some embodiments, a surface area of the second footprint may be larger than 1 mm². In some embodiments, the surface area of the second footprint may be larger than a surface area of a via. The surface area of the second footprint may be larger than a surface area of a micro-via. In some embodiments, the surface area of the first footprint may be large enough to accommodate at least two vias or micro-vias. In this embodiment, the surface area of the second footprint may be larger than a surface area covered by the at least two vias or micro-vias.

Advantageously, an increased surface area of the second footprint (i.e. a surface area larger than 1 mm²) allows for a lower electrical contact resistance and a lower thermal resistance of an electrical connection between the die contact pad and the one or more tracks.

The second footprint may be geometrically similar to the first footprint. The second footprint may comprise a uniformly scaled version of the first footprint. The second footprint may comprise a uniformly reduced version of the first footprint.

In some embodiments, a shape of the second footprint is identical to a shape of the first footprint. In this manner a shape of the opening in in a plane defined by the top surface of the die contact pad may be matched in geometry to that of the die contact pad. Additionally or alternatively, a size of the second footprint is identical to a size of the first footprint. The matched shape and size allows for an optimized interconnection between the die contact pad and the one or more tracks on the embedded die substrate. Advantageously, the optimized interconnection provides a lower electrical contact resistance and a lower thermal connection between the die and the one or more tracks.

The size of the second footprint may be 1-5% smaller than the size of the first footprint. The surface area of the second footprint may be 1-5% smaller than the surface area of the first footprint. The size of the second footprint may be 0.5%, 1%, 2%, 3%, 5%, 10%, 15%, 20%, 25% or 30% smaller than the size of the first footprint. The surface area of the second footprint may be 0.5%, 1%, 2%, 3%, 5%, 10%, 15%, 20%, 25% or 30% smaller than the surface area of the first footprint.

The first footprint may be non-symmetrical. The first footprint may be asymmetrical. The second footprint may be non-symmetrical. The second footprint may be asymmetrical.

It is often difficult to remove a portion of the dielectric layer to create an opening having a complex geometry. More specifically, it is challenging to remove a portion of the dielectric layer to create an opening which has a non-symmetrical or asymmetrical footprint in a plane defined by the top surface of the semiconductor contact pad. This is because, during a conventional manufacturing process, a high-powered laser is used to create a series of vias or micro-vias. It is difficult and time-consuming to use a series of vias or micro-vias to form an opening which has a complex geometry. The presently disclosed method is especially effective at removing a portion of the dielectric layer to create an opening having a complex, non-symmetrical geometry.

The die substrate may comprise a wide-bandgap (WBG) semiconductor. The wide-bandgap semiconductor may comprise an energy bandgap in a range above 2 eV. The semiconductor substrate may comprise an ultra-wide bandgap (UWBG) semiconductor. The ultra-wide bandgap semiconductor may comprise an energy bandgap in a range above 4 eV.

Power devices utilizing WBG and UWBG semiconductors offer significant advantages over their silicon counterparts, including reduced chip size, lower losses, and higher operational frequencies. These benefits translate into higher system efficiency and more compact form factors. However, one of the primary challenges in the development and deployment of WBG and UWBG devices is the efficient dissipation of heat, an inevitable consequence of their higher power density. The manufacturing method disclosed herein is especially effective at providing efficient thermal management, thereby addressing this critical challenge and enabling the full potential of WBG and UWBG semiconductors.

The semiconductor substrate may comprise Silicon Carbide (SiC). Additionally or alternatively, the semiconductor substrate may comprise Gallium Nitride (GaN).

The embedded die substrate may comprise a die carrier. A bottom surface of the die substrate may be connected to a top surface of the die carrier.

The die may further comprise a bottom contact pad. The bottom die contact pad may be connected to bottom surface of the die substrate. The bottom die contact pad may be connected to a side of the die substrate which is opposite to the side of the die substrate which comprises the die contact pad. The bottom die contact pad may be made out of the same material as the die contact pad. More specifically, the bottom die contact pad may comprise a conductive material. The bottom die contact pad may comprise copper. In order from top to bottom, the die may comprise one or more die contact pads, the die substrate and the bottom die contact pad. In this manner the die substrate may be sandwiched between the at least one die contact pad and the bottom die contact pad.

The bottom die contact pad may be connected to the die carrier. More specifically, a lower surface of the bottom die contact pad may be connected to the top surface of the die carrier. The bottom die contact pad may be connected to the die carrier using a die attach material.

If the bottom die contact pad does not require an electrical connection (i.e. the bottom die contact pad is isolated), the die attach material may comprise a thermally conductive and an electrically isolating substance. In this embodiment, the die attach material may comprise an electrically isolating thermal interface material.

If the bottom die contact pad does require an electrical connection, the die attach material may comprise a thermally and electrically conductive adhesive. In this embodiment, the die attach material may comprise a silver and/or copper filled sinter material.

The die carrier may comprise an upper base plate. The die carrier may comprise a die carrier dielectric. The die carrier may comprise a lower base plate. The die carrier dielectric may sit atop the lower base plate. The upper base plate may sit atop the die carrier dielectric.

The die attach material may sit atop the upper base plate. The bottom die contact pad may sit atop the die attach material. The die substrate may sit atop the bottom die contact pad. The one or more die contact pads may sit atop the die substrate. The dielectric layer may sit atop the one or more die contact pads, such that the top surface of the one or more die contact pads is covered by the dielectric layer prior to the step of removing the portion of the dielectric layer to create the opening. The one or more tracks may sit atop the top surface of the dielectric layer. The opening may provide an electrical connection in a vertical plane between the top surface of the one or more die contact pads and the one or more tracks.

The die carrier may comprise a heatsink. More specifically, the die carrier dielectric may comprise a heatsink. The heatsink may comprise a ceramic heatsink. The ceramic heatsink may comprise Aluminium Nitride. Advantageously, Aluminium Nitride comprises a second highest thermal conductivity of any ceramic material and comprises a very low coefficient for thermal expansion (CTE). The incorporation of a heat sink ensures an efficient heat dissipation from the die. The properties of Aluminium Nitride make it especially suited to allow for optimal heat dissipation from the die. The combination of matching the second footprint to the first footprint as well as providing the heatsink provides a synergistic effect of optimal heat dissipation from the die.

The upper base plate may comprise an upper copper plate. The lower base plate may comprise a lower copper plate. Advantageously the ceramic heatsink provides an excellent isolation and thermal conduction between the upper and lower copper plates. The lower copper plate helps to prevent the ceramic heatsink from fracturing during manufacturing. Additionally, the lower copper plate also provides a useful point where a cooler plate, an additional heatsink and/or a grounding connection may be added.

The opening may comprise at least a first opening and a second opening down to the top surface of the die contact pad. The first opening may comprise a first partial footprint in the plane defined by the top surface of the die contact pad. The second opening may comprise a second partial footprint in the plane defined by the top surface of the die contact pad. The first partial footprint and the second partial footprint may collectively form the second footprint.

The first opening and the second opening may extend from a top surface of the dielectric layer to the top surface of a single die contact pad. The first opening and the second opening may be separated by a wall of dielectric material. The first partial footprint and the second partial footprint may be spaced away or separated from each other in the plane defined by the top surface of the die contact pad.

The use of partial footprints offers more precise control over the distribution of thermal and electrical conductivity. Since the die generates substantial heat during operation, certain applications or designs require careful management of heat spread within the embedded die electronic device. In cases where a large die connection might transfer excessive heat along a particular conductor (i.e., through the opening filled with conductive material and the associated tracks), dividing a single large opening into two smaller openings can be advantageous. By adjusting the sizes of the first and second partial footprints, this method can mitigate excessive heat transfer to specific areas of the device, thereby preventing potential damage and maintaining optimal performance. This capability enables more sophisticated thermal management, enhancing the overall reliability and efficiency of the embedded die electronic device.

The second partial footprint may be larger than the first partial footprint. More specifically, a surface area covered by the second partial footprint may be larger than a surface area covered by the first partial footprint. This arrangement strategically allows for preferential heat dissipation along the conductors connected to the pad contact via the second opening. By designing the second opening to have a larger footprint, more heat can be channelled away from critical areas and dissipated efficiently through the associated conductors. This selective heat management approach ensures that thermal energy is directed along pathways that are better equipped to handle and dissipate it, thereby reducing the risk of overheating and potential damage to sensitive components. This method enhances the overall thermal management within the embedded die power electronic device, contributing to improved reliability and performance.

In some embodiments, the second partial footprint may partially wrap around the first partial footprint.

The embedded die substrate may further comprise a copper layer. The copper layer may form a top surface of the embedded die substrate. The copper layer may sit atop the dielectric layer. In other words, the dielectric layer may lie underneath the copper layer. The copper layer may cover the entire top surface of the underneath dielectric layer.

The method for manufacturing an embedded die electronic device may comprise removing a portion of the copper layer along with the portion of the dielectric layer to create the opening down to the top surface of the die contact pad.

Removing the portion of the copper layer along with the portion of the dielectric layer to create the opening may comprise a step of coating the top surface of the embedded die substrate with a protective layer. Subsequently, creating the opening may comprise a step of removing parts of the protective layer to expose the parts of the copper layer underneath. Creating the opening may comprise a step of chemically removing the exposed parts of the copper layer to expose the parts of the dielectric layer underneath. Creating the opening may comprise a step of removing the exposed parts of the dielectric layer to create the opening down to the top surface of the die contact pad.

The above method means a high-powered laser does not need to be used to drill through the copper layer and dielectric layer, since a low-powered laser can cut through just the dielectric layer. As such, the method reduces the risk of the die being damaged. Further, the lack of a high-powered laser also means the method is less expensive, and easier to implement.

It is difficult to form an exposed path on the die via a series of drilled vias or micro-vias, and so there is a limit to the variance in the connections which can be made between the circuitry atop the substrate and the die while using a high-powered laser. Advantageously, the above method of removing the portion of the effective at creating an opening which has a complex and/or a non-symmetrical geometry.

The protective layer may comprise a photoresist layer.

The method of manufacturing an embedded electronic device may comprise the additional step of exposing a light source to parts of the photoresist layer to alter the exposed parts of the photoresist layer. The method of manufacturing an embedded electronic device may comprise the step of applying a patterned mask over the photoresist layer, to prevent parts of the photoresist layer being exposed to the light. The patterned mask may define the one or more tracks. The method of manufacturing an embedded electronic device may comprise the step of removing the patterned mask once the parts of the photoresist layer have been exposed to the light.

The photoresist layer may be a positive photoresist layer. The photoresist layer may be a negative photoresist layer. The patterned mask may be a negative patterned mask. The patterned mask may be a positive patterned mask. The negative photoresist of the photoresist layer may polymerise when exposed to the light source. The photoresist of the positive photoresist layer may degrade when exposed to the light source, such that it dissolves when developer is applied. The photoresist of the negative photoresist layer may strengthen when exposed to the light source, such that it does not dissolve when developer is applied.

The light source exposed to parts of the photoresist layer to alter the exposed parts may be a laser. The laser may be a first low-powered laser. The first low-powered laser may be too low powered to cut through the copper layer. The light source may be a UV light source. The light source may be incoherent.

The parts of the protective layer (e.g., the photoresist layer) may be chemically removed to expose the parts of the copper layer underneath. The parts of the photoresist layer may be removed via the application of a developer to expose the parts of the copper layer underneath. The developer may form part of a developer solution. The developer solution may be an aqueous developer solution.

The parts of the photoresist layer exposed to the light source may be the parts removed to expose parts of the copper layer. Alternatively, the parts of the photoresist layer not exposed to the light source may be the parts removed to expose parts of the copper layer.

The exposed parts of the copper may be chemically removed by the application of a first chemical solution to expose the parts of the dielectric layer underneath. The protective layer may be unreactive to the first chemical solution. The protective layer may be resistant to the first chemical solution. The protective layer may be chemically inert to the first chemical solution. The first chemical solution may be a chemical etchant solution.

Removing the exposed parts of the dielectric layer may comprise using a low-powered laser to cut through the exposed parts of the dielectric layer to create the opening down to the top surface of the die contact pad.

The low-powered laser may be a broad beam laser. The low-powered laser may be a scanning laser. The laser may be a second low-energy laser. The laser may be a CO2 laser. The laser may be too low powered to cut through the copper layer. The laser may be too low powered to damage the chip. The laser may perform laser ablation on the exposed parts of the dielectric layer to expose the parts of the embedded die underneath. The copper layer, with the parts removed in it, may form a laser ablation mask.

Advantageously, the opening down to the top surface of the die contact pad may be less than the width of the laser. This means a laser with a wide beam can be used to achieve a narrow opening down to the top surface of the die contact pad. Consequently, an opening having a complex geometry can be easily created. Additionally, using a low-power laser means that the die is less likely to be damaged during the manufacturing process. As such, the method disclosed herein is especially suited to creating an opening which has a footprint that matches a footprint of a complex and non-symmetrical die contact pad.

The method of manufacturing an embedded die electronic device may comprise the step of removing the remaining parts of the protective layer once the exposed parts of the copper layer are removed. The method of manufacturing an embedded die electronic device may comprise the step of removing the remaining parts of the protective layer once the parts of the dielectric layer underneath are exposed.

The remaining protective layer may be chemically removed. The remaining protective layer may be chemically removed by the application of a second chemical solution. The copper layer may be unreactive to the second chemical solution. The copper layer may be resistant to the second chemical solution. The copper layer may be chemically inert to the second chemical solution. The copper layer may be unreactive to the developer. The copper layer may be resistant to the developer. The copper layer may be chemically inert to the developer. The second chemical solution may be a resist stripping chemical solution.

Any or all of the developer, first chemical solution and/or second chemical solution may be applied via any of the following: a respective spray, tray flood unit and/or static tank.

The one or more tracks may be formed on a top surface of the dielectric layer. The one or more tracks may comprise a third footprint in a plane defined by the top surface of the dielectric layer. A surface area covered by the third footprint may be larger than the surface area covered by the first footprint. Additionally or alternatively, the surface area covered by the third footprint may be larger than the surface area covered by the second footprint.

A larger third footprint increases the current-carrying cross section, which can effectively reduce the electrical resistance of the conductors. This expanded cross-sectional area helps to distribute the current more evenly, thereby lessening the potential for current crowding, which can lead to localized heating and reduced efficiency. As a result, this design improves the overall current handling capability of the embedded die electronic device, enhancing its performance, reliability, and longevity.

The third footprint may at least partially overlap the first footprint and the second footprint. The third footprint may fully overlap the first footprint and the second footprint. The third footprint may at least partially overlap the first partial footprint and the second partial footprint. The third footprint may fully overlap the first partial footprint and the second partial footprint.

In some embodiments, the die comprises a die substrate having a first die contact pad and a second die contact pad. Both the first die contact pad and the second die contact pad sit atop the die substrate. The first die contact pad and the second die contact pad may sit side-by-side on the surface of the die substrate.

The method may comprise a step of removing a portion of the dielectric layer to create an opening down to the top surface of the first die contact pad. The method may not comprise a step of removing a portion of the dielectric layer to create an opening down to the top surface of the second die contact pad. The method may comprise a step of forming one or more tracks on the embedded die substrate, wherein forming the one or more tracks may comprise filling in the opening down to the first die contact pad with a conductive material. The one or more tracks may comprise a third footprint in a plane defined by the top surface of the dielectric layer. The third footprint may overlap at least a portion of the first die contact pad and at least a portion of the second die contact pad. The third footprint may fully overlap the first die contact pad and partially overlap the second die contact pad. The embedded die electronic device may comprise a layer of dielectric material between the second die contact pad and the one or more tracks (i.e., the second die contact pad is not electrically connected to the one or more tracks).

The size and shape of the third footprint may be defined by the specific isolation gap required to avoid electrical shorting between the second die contact pad and one or more tracks having the third footprint. For example, for a semiconductor having a specific voltage, encapsulated in a non-conductive material with a specific dielectric breakdown value, the gap between the second die contact pad and one or more tracks having the third footprint may comprise a minimum of isolation gap required to prevent the shortening. The third footprint may occupy the maximum space available, minus the required isolation gap as defined by the material properties.

The third footprint may be geometrically similar to both the second footprint and the first footprint. The third footprint may comprise an enlarged version of the first footprint and/or the second footprint.

The one or more tracks may be attached to the at least one die contact pad using additive manufacturing. The additive manufacturing may comprise plating, metallic sintering and/or using a conductive adhesive.

The die may comprise a chip.

According to a second aspect of the present invention there is provided an embedded die electronic device manufactured according to any method described herein.

The skilled person will appreciate that except where mutually exclusive, a feature described in relation to any one of the aspects, methods, examples or embodiments described herein may be applied to any other method, aspect, example, embodiment or feature. Further, the description of any aspect, method, example or feature may form part of or the entirety of an embodiment of the invention as defined by the claims. Any of the examples described herein may be an example which embodies the invention defined by the claims and thus an embodiment of the invention.

### BRIEF DESCRIPTION OF THE DRAWINGS

In order that the invention may be more clearly understood one or more embodiments thereof will now be described, by way of example only, with reference to the accompanying drawings, of which:

FIG. 1 shows a cross-sectional view of an embedded die substrate.

FIG. 2 shows a plan view of the die depicted in FIG. 1.

FIG. 3 shows a cross-sectional view of the embedded die substrate comprising a series of conventional micro-via connections.

FIG. 4 shows a plan view the die depicted in FIG. 1 showing positions of the series of conventional micro-via connections.

FIG. 5A-F show cross-sectional views of the embedded die substrate at various stages during a method for manufacturing an embedded die electronic device in accordance with the present disclosure.

FIG. 6 shows a cross-sectional view of a first example of an embedded die electronic device in accordance with the present disclosure.

FIG. 7A shows a plan view of the first example of an embedded die electronic device shown in FIG. 6.

FIG. 7B shows a zoomed-in view of area A shown in FIG. 7A.

FIG. 8 shows a plan view of the second example of an embedded die electronic device in accordance with the present disclosure.

FIG. 9 shows a cross-sectional view of the second example of an embedded die electronic device in accordance with the present disclosure.

FIG. 10 shows a cross-sectional view of the third example of an embedded die electronic device in accordance with the present disclosure.

### DETAILED DESCRIPTION OF THE INVENTION

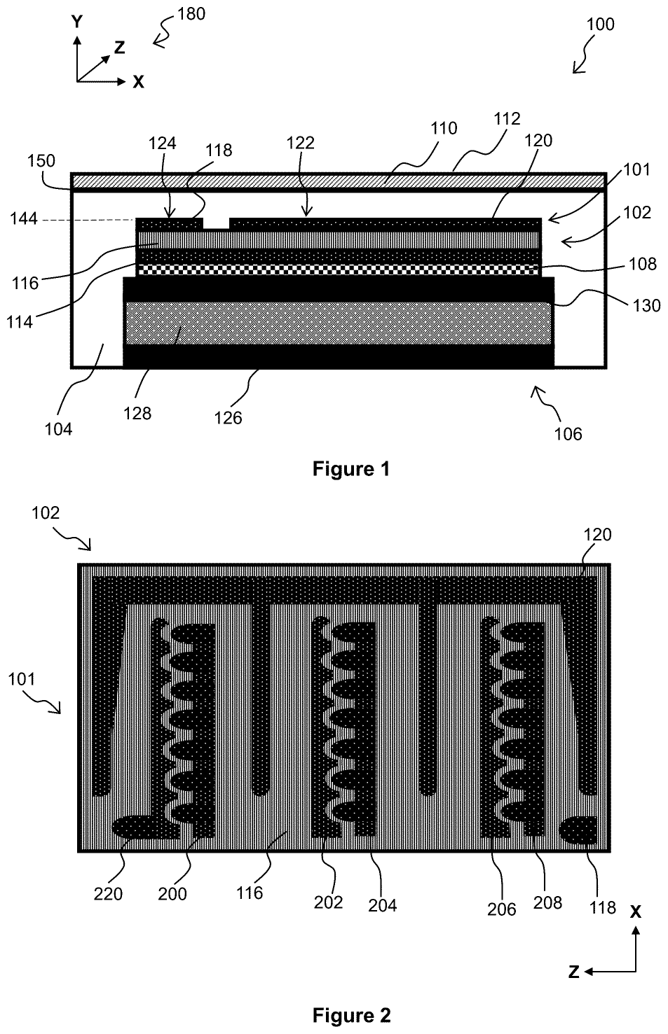

FIG. 1 shows a cross-sectional view of an embedded die substrate 100. The embedded die substrate 100 comprises a copper layer 110, a dielectric layer 104, a die 102, a die attach material 108 and a die carrier 106. FIG. 1 shows an axes 180, which defines a vertical y-axis, a horizontal x-axis and longitudinal z-axis.

The copper layer 110 forms a top surface 112 of the embedded die substrate 100. The die carrier 106 and a portion of the dielectric layer 104 for a bottom surface of the embedded die substrate 100. The dielectric layer 104 comprises a top surface 150. The die attach material 108 sits atop the die carrier 106. The die 102 sits atop the die attach material 108. The die 102 is attached to the die carrier 106 via the die attach material 108. The die 102, the die attach material 108 and the die carrier 106 are embedded within the dielectric layer 104, such that at least a portion of the dielectric layer 104 covers the entire top surface of the die 102. The copper layer 110 sits atop the top surface 150 of the dielectric layer 104. In order from top to bottom, along the vertical y axis, the embedded die substrate 100 comprises the copper layer 110, a portion of the dielectric layer 104, the die 102, the die attach material 108 and the die carrier 106.

In this embodiment, the dielectric layer 104 comprises an epoxy resin and the die attach material 108 comprises a thermally and electrically conductive material.

The die 102 comprises a bottom die contact pad 114, a die substrate 116 and a plurality of die contact pads 101. The plurality of die contact pads 101 include a first die contact pad 118 and a second die contact pad 120. The remainder of the die contact pads 101 are best visible in FIG. 2.

The bottom die contact pad 114 is made out of copper. The bottom die contact pad 114 sits atop the die attach material 108. In this manner the bottom die contact pad 114 (and consequently the die 102 as a whole) is connected to the die carrier 106 via the die attach material 108.

The die substrate 116 comprises a wide-bandgap (WBG) semiconductor. More specifically, the die substrate 116 comprises Gallium Nitride (GaN). The die substrate 116 sits atop the bottom die contact pad 114.

Power devices utilizing WBG semiconductors offer significant advantages over their silicon counterparts, including reduced chip size, lower losses, and higher operational frequencies. These benefits translate into higher system efficiency and more compact form factors. However, one of the primary challenges in the development and deployment of WBG devices is the efficient dissipation of heat, an inevitable consequence of their higher power density. A method for manufacturing an embedded die electronic device disclosed herein is especially effective at providing efficient thermal management, thereby addressing this critical challenge and enabling the full potential of WBG semiconductors.

The first die contact pad 118 and the second die contact pad 120 are made out of copper. The first die contact pad 118 comprises a first top surface 124 and the second die contact pad 120 comprises a second top surface 122. The first die contact pad 118 and the second die contact pad 120 sit side-by-side atop the die substrate 116. The first die contact pad 118 and the second die contact pad 120 are separated along the horizontal x-axis by a portion of the dielectric layer 104. The first top surface 124 and the second top surface 122 sit at the same vertical level on the y-axis. A plane defined by the first top surface 124 and the second top surface 122 of the die contact pads (a plane defined along the x-z axis) is shown by a dashed line 144 in FIG. 2.

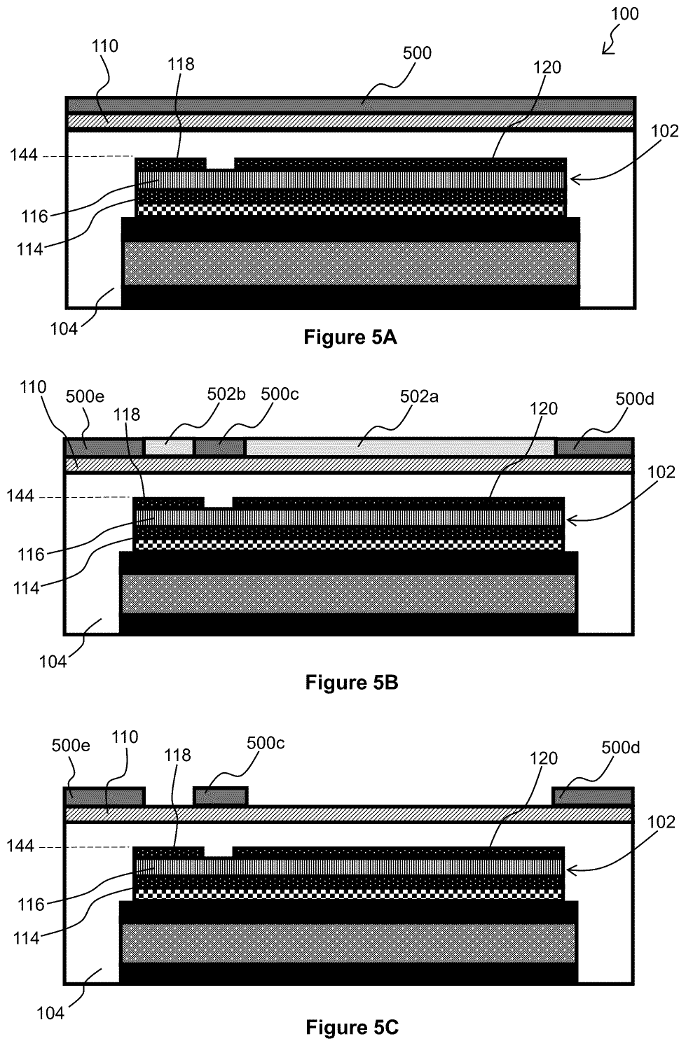

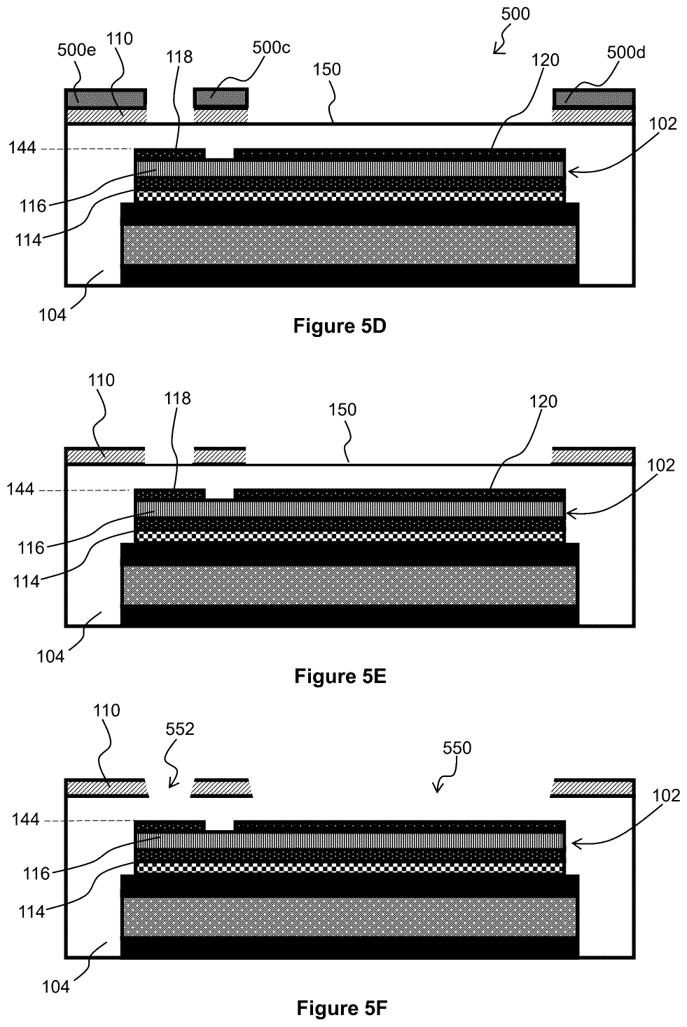

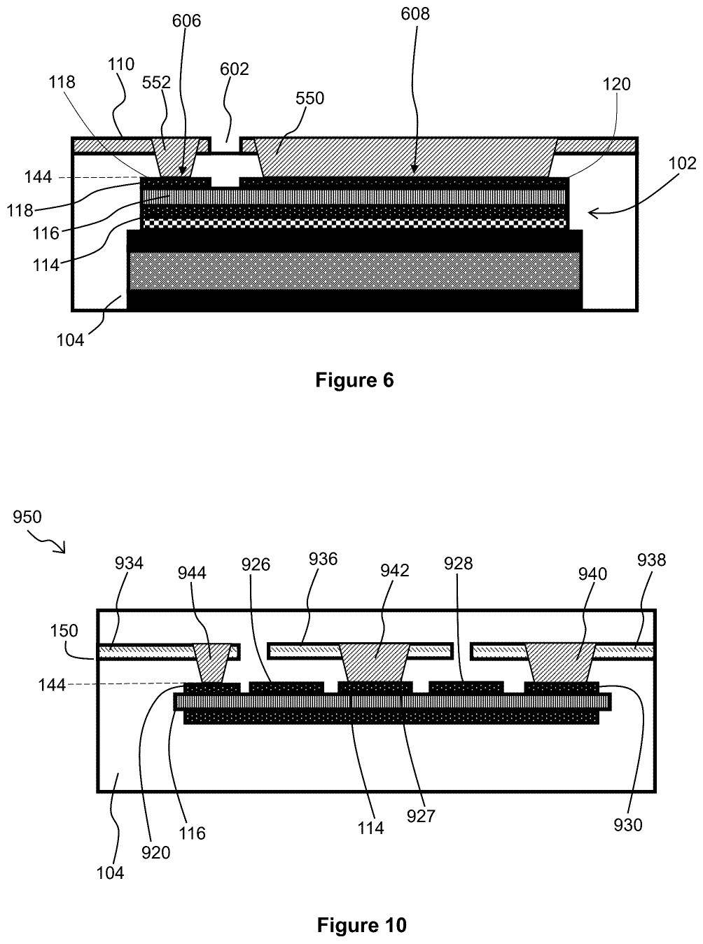

At least a portion of the copper layer 110 and at least a portion of the dielectric layer 104 have to be removed in order to create an electrical connection (along the vertical y-axis) between the copper layer 110 and the first top surface 124 of the first die contact pad 118 and/or between the copper layer 110 and the second top surface 122 of the second die contact pad 120. This process, according to the present disclosure, will be described in more detail with reference to FIGS. 5A-5F and FIG. 6.

The die carrier 106 comprises an upper base plate 130, a die carrier dielectric 128 and a lower base plate 126.

The upper base plate 130 and the lower base plate 126 are made out of copper. In other words, the upper base plate 130 may be labelled as an upper copper plate and the lower base plate 126 may be labelled as a lower copper plate. The die carrier dielectric 128 comprises a ceramic heatsink. More specifically, the die carrier dielectric 128 is made out of Aluminium Nitride.

The die carrier dielectric 128 sits atop the lower base plate (i.e., the lower copper plate) 126. The upper base plate (i.e. the upper copper plate) 130 sits atop the die carrier dielectric 128. In this manner, the die carrier dielectric 128 is sandwiched between the lower base plate 126 and the upper base plate 130.

Advantageously, Aluminium Nitride comprises a second highest thermal conductivity of any ceramic material and comprises a very low coefficient for thermal expansion (CTE). The incorporation of a heat sink into the embedded die substrate ensures an efficient heat dissipation from the die 102. The properties of Aluminium Nitride make it especially suited to allow for optimal heat dissipation from the die 102.

Advantageously the ceramic heatsink 128 provides an excellent isolation and thermal conduction between the upper 130 and lower 126 copper plates. The lower copper plate 126 helps to prevent the ceramic heatsink 128 from fracturing during manufacturing. Additionally, the lower copper plate 126 also provides a useful point where a cooler plate, an additional heatsink and/or a grounding connection may be added. This acts to improve the heat dissipation away from the die 102.

Turning now to FIG. 2 there is shown a plan view of the die 102 depicted in FIG. 1. More specifically, FIG. 2 shows a top-down view of the plane 144 defined by the top surfaces of the die contact pads 101 (a plane defined along the x-z axis).

FIG. 2 shows the die substrate 116 and the plurality of die contact pads 101.

The plurality of die contact pads 101 includes the first die contact pad 118, the second die contact pad 120, a third die contact pad 220, a fourth die contact pad 200, a fifth die contact pad 202, a sixth die contact pad 204, a seventh die contact pad 206 and an eighth die contact pad 208. The third, fourth, fifth, sixth, seventh and eight die contact pads are all made out of copper and all sit at the same vertical level 144 on top of the die substrate 116. More specifically, the top surface of each die contact pad sits at the same vertical level (indicated by plane 144 in FIG. 1). A skilled person would recognise that the die may comprise more or fewer die contact pads, as required for a particular embedded die electronic device.

The plurality of die contact pads 101 each comprise a respective footprint in the plane 144 (plane defined by the top surface of each of the die contact pads). More specifically, the first die contact pad 118 comprises a first footprint, the second die contact pad 120 comprises a another (e.g., fifth) footprint and so on. In other words, the top surface 124 of the first die contact pad comprises the first footprint, the top surface 122 of the second die contact pad 120 comprises another (e.g., fifth) footprint and so on. These footprints are visible in FIG. 2. The skilled person would understand that the specific labels (e.g., first, fifth etc.) given to the footprints are immaterial and may be changed.

The respective footprints of the die contact pads 101 each have a complex geometry. In one example, each footprint of the plurality of the die contact pads 101 may have a composite shape, appearing as a combination of several geometric shapes merged together. The third die contact pad 220, the fourth die contact pad 200, the fifth die contact pad 202, the sixth die contact pad 204, the seventh die contact pad 206 and the eighth die contact pad 208 all comprise non-symmetrical footprints. A skilled person will recognise that the footprints of the die contact pads 101 may comprise any shape. For example, the footprints of the die contact pads 101 may comprise any irregular, organic or curvilinear shape.

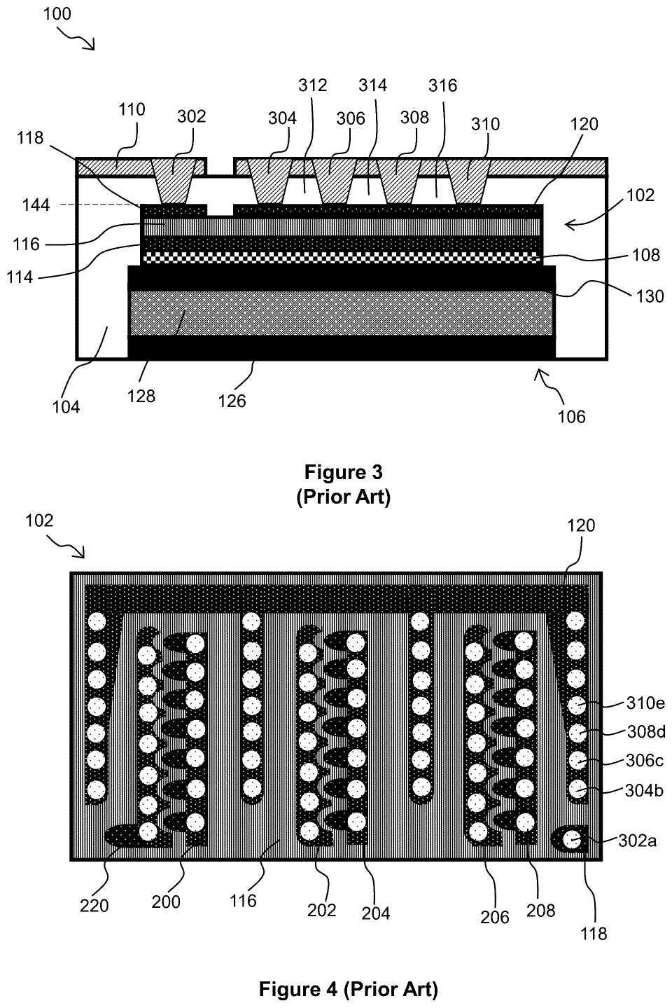

A conventional manufacturing process for removing portions of the copper layer 110 and portions of the dielectric layer 104 to create one or more openings down to the top surface 124, 122 of the die contact pads 118, 120 will now be described with reference to FIGS. 3 and 4.

During a conventional chip or die embedding processes, there is provided the embedded die substrate 100. Subsequently, mainstream Printed Circuit Board (PCB) manufacturing style vias or micro-vias 302, 304, 306, 308, 310 are drilled through the copper layer 110 and the dielectric layer 104 using a high-powered laser (e.g. a CO2 laser). This step makes vertical holes (in a shape of a cylinder or a conical frustum) extending from the underlying die contact pads 118, 120, 220, 200, 202, 204, 206, 208 of the die 102 to overlying circuitry on the top surface 150 of the dielectric layer 104. Subsequently, a copper plating or metallization process is conducted to connect the contact pads of the die 102 to the copper layer 110. The final step comprises a circuit patterning process, which is conducted to create a desired circuit layout. An example of embedded electronic device manufactured using this conventional method is shown in FIG. 3.

FIG. 3 shows a cross-sectional view of the embedded die substrate 100 comprising plurality of conventional micro-via connections 302, 304, 306, 308, 310. A first micro-via 302 connection extends down to the first die contact pad 118. A second 304, a third 306, a fourth 308, and fifth micro-via connections extend down to the second die contact pad 120.

FIG. 4 shows a plan view the die 102 depicted in FIG. 1 showing positions of the series of conventional micro-via connections 302, 304, 306, 308, 310. More specifically, FIG. 4 shows a top-down view of the plane 144 defined by the top surfaces of the die contact pads 101 (a plane defined along the x-z axis).

As shown in FIG. 4, the micro-vias 302, 304, 306, 308, 310 comprise respective circular footprints 302a, 304b, 306c, 308d, 310e in the plane 144 defined by the top surface 124, 122 of the die contact pads 118, 120. For the sake of simplicity not all of the micro-via footprints have been labelled.

As can be seen, the circular footprints 302a, 304b, 306c, 308d, 310e of the conventional micro-via connections 302, 304, 306, 308, 310 do not match the respective footprints of the die contact pads 118, 120, 220, 200, 202, 204, 206, 208 to which they are connected. This is because their circular shape doesn't match the complex geometrical shape of the respective footprints of the die contact pads 118, 120, 220, 200, 202, 204, 206, 208. Additionally, total surface area covered by the circular footprints 302a, 304b, 306c, 308d, 310e is substantially smaller than the surface area covered by the respective footprints of the die contact pads 118, 120, 220, 200, 202, 204, 206, 208 to which they are connected.

This conventional manufacturing approach introduces a matrix of electrically and thermally insulating material 312, 314, 316 (shown in FIG. 3) within areas that would benefit from uninterrupted connections. This configuration creates thermal bottlenecks, limiting the effective dissipation of heat from the die 102. As a result, elevated temperatures may compromise device performance and reliability.

Historically, arrays of PCB-style micro-vias have been employed to establish connections between die contact pads and any overlying circuitry. Consequently, machines designed to facilitate this process have been exclusively used in the field of die embedding. This longstanding reliance has fostered a technical prejudice towards the use of micro-vias for creating electrical connections within embedded die substrates.

A method for creating openings from the top surface 112 of the copper layer 110 down to the top surface of the die contact pads 101 in accordance with the present disclosure will now be described with reference to FIGS. 5A-5F.

FIG. 5A-5F show cross-sectional views of the embedded die substrate 100 at various stages during a method for manufacturing an embedded die electronic device in accordance with the present disclosure.

In FIG. 5A, a negative photoresist layer 500 is applied to cover the entire top surface 112 of the embedded die substrate 100. Moving to FIG. 5B, a low-powered UV laser is then applied to parts 502c, 502d, 502e of the negative photoresist layer 500, resulting in parts of the negative photoresist layer 500 being polymerised. The remaining parts 502b, 502a form a pattern on the top surface of the embedded die substrate 100, the pattern determined by the user's requirements.

In FIG. 5C, a developer sprayer is used to apply a spray of an aqueous developer solution to the negative photoresist layer 500. The developer dissolves the unpolymerized parts 502a, 502b of the photoresist layer 500, exposing the parts of the copper layer 110 beneath.

In other embodiments a negative patterned mask and an incoherent UV light source can be used instead of a laser. The mask forms a transparent layer with a blocking pattern in the transparent layer. The mask is laid over the photoresist layer, and the top of the mask is then exposed to the light source. The blocking pattern blocks the light from reaching the photoresist layer, but the transparent areas allow light through to the parts of the photoresist layer beneath. The mask is then removed, and the developer is applied. The parts of the photoresist layer not exposed to the light source (i.e. the parts underneath the blocking pattern) are then dissolved.

In other embodiments a positive photoresist layer 500 and positive pattern mask are used. The mask is a blocking layer with a transparent pattern in it. The mask is applied atop the photoresist layer 500, and then is exposed to the light source. The blocking layer areas prevent light from reaching the parts of the photoresist layer 500 beneath, but the parts beneath the transparent pattern of the photoresist layer 500 are exposed to the light. The light degrades the parts of the photoresist layer 500 exposed to the light. Then, when the mask is removed and the developer is applied to the photoresist layer 500, only the parts of the photoresist layer 500 not underneath the blocking areas (i.e. underneath the transparent pattern) will dissolve.

Finally, in other embodiments a positive photoresist layer 500 and low powered UV laser are used. The low powered UV laser is applied to the parts 502a, 502b of the photoresist layer 500 forming a pattern, degrading them. The application of the developer then removes these parts 502a, 502b.

The removed parts 502a, 502b form a series of openings across the embedded die substrate 100, each opening may have a complex geometrical footprint in a plane defined by the top surface 112 of the embedded die substrate 100.

Moving to FIG. 5D, a chemical etchant solution is sprayed over the photoresist layer 500 and exposed parts of the copper layer 110. The chemical etchant solution dissolves the exposed parts of the top copper layer 110, exposing the parts of the dielectric layer 104 underneath. The photoresist layer 500 is resistant to the chemical etchant solution, such that it doesn't dissolve upon application of the chemical etchant solution. Thereby, the openings are deepened, taken down to the top surface 150 of the dielectric layer 104.

Moving to FIG. 5E, a resist stripper chemical solution is sprayed onto the remaining parts of the photoresist layer 500, dissolving it. The copper layer 110 is resistant to the resist stripper chemical solution, and so does not dissolve. This results in the remaining parts 500e, 500c, 500d of the photoresist layer 500 being entirely removed.

Turning to FIG. 5F, a low-powered, wide beam CO2 laser applies laser energy to the exposed parts of the dielectric layer 104. The low-powered, wide beam CO2 laser carries out laser ablation, with the copper layer acting as a laser ablation mask. The width and/or diameter of the openings is less than the width of the low-powered, wide beam CO2 laser. This means that the low powered laser can cut openings having any complex geometrical shape. The laser energy cuts through the exposed dielectric layer 104, exposing the parts of the top surface 124, 120 of the first dielectric contact pad 118 and the second dielectric contact pad 120. The low-powered CO2 laser is too low powered to cut through the copper layer 110 or damage the die 102. The openings are thereby deepened again, down to the top surfaces 124, 120 of the respective first dielectric contact pad 118 and the second dielectric contact pad 120. These openings are shown as a first opening 552 and a second opening 550, respectively.

Turning to FIG. 6, there is shown an example of an embedded electronic device manufactured in accordance with the disclosed method. During the last manufacturing steps, the first opening 552 and the second opening 550 are filled in with conductive material (e.g. copper) in a known manner. Subsequently, tracks are then formed in the copper layer 110 (for example, by removing a part 602 of the copper layer 110), the tracks have an electrical connection to the respective the first dielectric contact pad 118 and the second dielectric contact pad 120, as required by a specific embedded die electronic device.

The first opening 552 comprises a second footprint 606 in the plane 144 defined by the top surfaces of the die contact pads 101 (best shown in FIG. 1). Similarly, the second opening 550 comprises a fourth footprint 608 in the plane 144 defined by the top surface of the die contact pads 101 (best shown in FIG. 1).

A skilled person would appreciate that other methods such as UV-YAG laser ablation, water jet cutting, grit blasting and micro-CNC machining, and other material removal processes may be employed to create openings from the top surface 112 of the copper layer 110 down to the top surface of the die contact pads 101. However, the method disclosed herein with reference to FIGS. 5A-5F and FIG. 6 is especially effective at quickly removing a portion of the copper layer 110 and a portion of the dielectric layer 104 in a complex geometry without damaging the die 102.

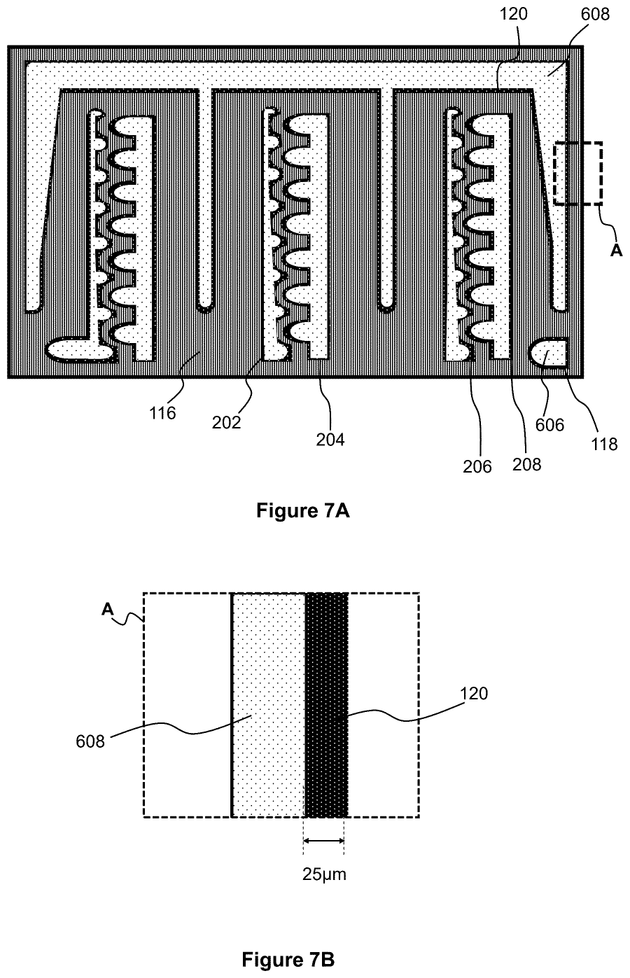

FIG. 7A shows a plan view of the embedded die electronic device depicted in FIG. 6. In this figure it is clearly visible that the second footprint 606 of the first opening 552 matches the first footprint of the first die contact pad 118. More specifically, the size of a surface area covered by the second footprint 606 is substantially similar to the size of the surface area covered by the first footprint. Additionally, a shape of the second footprint 606 is identical to a shape of the first footprint. More specifically, the second footprint 606 is geometrically similar to the first footprint.

Similarly, the fourth footprint 608 of the second opening 550 matches the fifth footprint of the second die contact pad 120. Although not specifically labelled (for the sake of simplicity), it is also shown that the footprints of the remaining openings match the respective footprints of the remaining die contact pads 220, 200, 202, 204, 206, 208.

FIG. 7A also shows a specific area A. FIG. 7B shows a zoomed-in view of the area A shown in FIG. 7A. FIG. 7B more clearly shows a separation between an outer edge of the fourth footprint 608 and an outer edge of the fifth footprint of the second die contact pad 120. There is a continuous 25 μm separation (known as radial land) between an outer edge of the fourth footprint 608 and an outer edge of the fifth footprint of the second die contact pad 120. The 25 μm radial land is also present between the second footprint 606 of the first opening 552 and the first footprint of the first die contact pad 118. Similarly, all of the remaining openings (not labelled) also comprise the 25 μm radial land. Advantageously, this amount of the radial land exposes a sufficient amount of the contact pad 118, 120 to ensure an optimal conductive material fill, thereby enhancing the thermal and electrical connectivity between the die 102 and any tracks and/or circuitry atop the embedded die substrate 100.

The disclosed method of manufacturing the embedded die electronic device offers significant improvements over the existing manufacturing techniques by addressing key limitations in thermal management and manufacturing efficiency for embedded electronic devices. By creating the openings 552, 550 (in the dielectric layer 104 and the copper layer 110) that match the respective footprints of the die contact pads 118, 120, the method ensures optimal conductive material fill, thereby enhancing the thermal and electrical connectivity between the die 102 and any circuitry atop the embedded die substrate 100 (e.g., any tracks manufactured on the top surface 150 of the dielectric layer 104). Advantageously, the claimed method reduces thermal resistance, facilitating more efficient heat dissipation from the die 102. Additionally, the combination of matching the second footprint to the first footprint as well as providing the heatsink 128 provides a synergistic effect of optimal heat dissipation from the die 102.

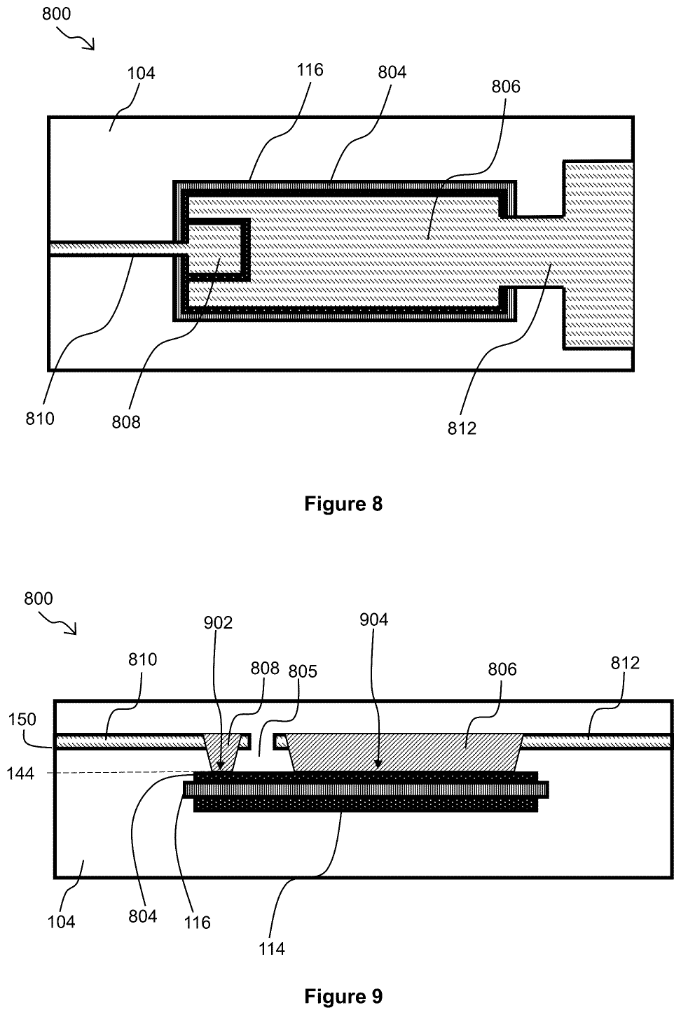

A second example of an embedded die electronic device in accordance with the present disclosure will now be described with reference to FIGS. 8 and 9.

FIG. 8 shows a plan view of the second example of an embedded die electronic device 800. FIG. 9 shows a cross-sectional view of the second example of the embedded die electronic device 800.

In this example, the embedded die electronic device 800 comprises a die having the bottom die contact pad 114, the die substrate 116 and a single top die contact pad 804. The embedded die electronic device 800 further comprises the dielectric layer 104. The die is embedded within the dielectric layer 104. In this embodiment, the embedded die electronic device 800 does not comprise the die carrier 106. Although a skilled person will understand that a die carrier may be incorporated as needed. The top die contact pad 804 comprises a top surface having a rectangular footprint. The embedded electronic device 800 further comprises a first track 810 and a second track 812 sitting on the top surface 150 of the dielectric layer 104.

In this embodiment, a first opening 808 and a second opening 806 extend from the top surface 150 of the dielectric layer 104 to the top surface of the single top die contact pad 804. The first opening 808 and the second opening 806 are separated by a wall 805 of dielectric material 104. The first opening 808 comprises a first partial footprint 902 in the plane 144 defined by the top surface of the die contact pad 804. The second opening 806 comprises a second partial footprint 904 in the plane 144 defined by the top surface of the die contact pad 804. The first partial footprint 902 and the second partial footprint 904 collectively substantially match the rectangular footprint of the top die contact pad 804. More specifically, a total surface area covered by both the first partial footprint 902 and the second partial footprint 904 is substantially similar to the surface area covered by the rectangular footprint of the top die contact pad 804.

The second partial footprint 904 is larger than the first partial footprint 902. More specifically, a surface area covered by the second partial footprint 904 is larger than a surface area covered by the first partial footprint 902. The second partial footprint 904 partly surrounds the first partial footprint 902 in the plane 144.

The first opening 808 and the second opening 806 are filled with conductive material. Conductive material within the first opening 808 is electrically connected to the first track 810. Conductive material within the second opening 806 is electrically connected to the second track 812.

This arrangement of partial footprints 902, 904 strategically allows for preferential heat dissipation along the track 812 connected to the pad contact 804 via the second opening 806. By designing the second opening 806 to have a larger footprint 904, more heat can be channelled away from critical areas and dissipated efficiently through the track 812. This selective heat management approach ensures that thermal energy is directed along pathways that are better equipped to handle and dissipate it, thereby reducing the risk of overheating and potential damage to sensitive components of the embedded die electronic device 800. This method enhances the overall thermal management within the embedded die electronic device, contributing to improved reliability and performance.

FIG. 10 shows a cross-sectional view of a third example of an embedded die electronic device 950 in accordance with the present disclosure.

In this example, the embedded die electronic device 950 comprises a die having the bottom die contact pad 114, the die substrate 116, a first die contact pad 920, a second die contact pad 926, a third die contact pad 927, a fourth die contact pad 928 and a fifth die contact pad 930. The first 920, second 926, third 927, fourth 928 and fifth 930 die contact pads are spaced apart from each along the horizontal x-axis (shown in FIG. 1). The first 920, second 926, third 927, fourth 928 and fifth 930 die contact pads all sit atop the die substrate 116 and the top surfaces of the contact pads 920, 926, 927, 828, 930 are positioned at the same vertical level indicated by the plane 144.

The embedded electronic device 950 further comprises the dielectric layer 104. The die is embedded within the dielectric layer 104. In this embodiment, the embedded electronic device 950 does not comprise the die carrier. Although a skilled person will understand that a die carrier may be incorporated as needed.

The embedded electronic device 950 further comprises a first opening 944 down to the top surface of the first die contact pad 920, a second opening 942 down to the top surface of the third die contact pad 927 and a third opening 940 down to the top surface of the fifth die contact pad 930. Each opening 944, 942, 940 comprises a footprint in a plane defined by the top surfaces of the die contact pads, which matches the footprint of the respective die contact pad 920, 927, 930 (as described with reference to previous Figures). The openings 944, 942, 940 are filled in with conductive material. No openings are created down to the second 926 and fourth 928 die contact pads. In this manner, the second 926 and fourth 928 die contact pads are not connected to the overlaying tracks.

Conductive material within the first opening 944 is connected to a first track 934. Conductive material within the second opening 942 is connected to a second track 936. Conductive material within the third opening 940 is connected to a third track 938. The tracks 934, 936, 938 all sit atop the top surface 150 of the dielectric layer 104. The first track 934 comprises a third footprint in a plane defined by the top surface of the dielectric layer 104. Similarly the second track 936 comprises a sixth footprint in a plane defined by the top surface of the dielectric layer 104 and the third track 938 comprises a seventh footprint in a plane defined by the top surface of the dielectric layer 104.

Surface area covered by the third footprint is larger than the surface area covered by the footprint of the top surface of the first die contact pad 920. Similarly, surface areas covered by the sixth and seventh footprints are larger than the surface areas covered by the footprint the respective third 927 and fifth 930 die contact pads.

In this embodiment, the sixth footprint of the second track 936 partially overlaps the second die contact pad 926 and the fourth die contact pad 928. A portion of the dielectric layer 104 separates the second die contact pad 926 and the fourth die contact pad 928 from the second track 936.

Advantageously, the larger footprints of the tracks 934, 936, 938 increase the current-carrying cross section, which can effectively reduce the electrical resistance. This design improves the overall current handling capability of the embedded die electronic device 950, enhancing its performance, reliability, and longevity.

It will be understood that the invention is not limited to the examples and embodiments above-described and various modifications and improvements can be made without departing from the concepts described herein. Except where mutually exclusive, any of the features may be employed separately or in combination with any other features and the disclosure extends to and includes all combinations and sub-combinations of one or more features described herein.

What is claimed is:

1. A method for manufacturing an embedded electronic device, the method comprising:
providing an embedded die substrate having a dielectric layer and a die at least partially embedded within the dielectric layer, the die comprising a die substrate and at least one die contact pad atop the die substrate, wherein the die contact pad comprises a top surface having a first footprint;
removing a portion of the dielectric layer to create an opening down to the top surface of the die contact pad, the opening comprising a second footprint in a plane defined by the top surface of the die contact pad, wherein the second footprint substantially matches the first footprint;
forming one or more tracks on the embedded die substrate, wherein forming the one or more tracks comprises filling in the opening with a conductive material.

2. A method according to claim 1, wherein the opening does not comprise a via or a micro-via and/or wherein the process of removing a portion of the dielectric layer does not comprise creating vias or micro-vias.

3. A method according to claim 1, wherein a surface area of the second footprint is larger than 1 mm².

4. A method according to claim 1, wherein the second footprint is geometrically similar to the first footprint.

5. A method according to claim 4, wherein the shape and size of the second footprint is identical to the shape and size of the first footprint or wherein the size of the second footprint is 1-5% smaller than the size of the first footprint.

6. A method according to claim 1, wherein the first footprint and/or the second footprint is non-symmetrical.

7. A method according to claim 1, wherein the die substrate comprises a wide-bandgap semiconductor.

8. A method according to claim 7, wherein the die substrate comprises Silicon Carbide and/or Gallium Nitride.

9. A method according to claim 1, wherein:
the embedded die substrate further comprises a die carrier, wherein a bottom surface of the die is connected to a top surface of the die carrier and the die carrier comprises a heat sink.

10. A method according to claim 1, wherein the opening comprises at least a first opening and a second opening down to the top surface of the die contact pad; and wherein
the first opening comprises a first partial footprint in the plane defined by the top surface of the die contact pad; and
the second opening comprises a second partial footprint in the plane defined by the top surface of the die contact pad;
the first partial footprint and the second partial footprint collectively forming the second footprint.

11. A method according to claim 10, wherein the second partial footprint is larger than the first partial footprint.

12. A method according to claim 10, wherein the second partial footprint at least partly wraps around the first partial footprint.

13. A method according to claim 1, wherein the embedded die substrate further comprises a copper layer, the copper layer forming a top surface of the embedded die substrate, wherein the dielectric layer lies underneath the copper layer and wherein the method comprises:
removing a portion of the copper layer along with the portion of the dielectric layer to create the opening down to the top surface of the die contact pad.

14. A method according to claim 13, wherein removing the portion of the copper layer along with the portion of the dielectric layer to create the opening comprises the steps of:
coating the top surface of the embedded die substrate with a protective layer, wherein the protective layer is a photoresist layer;
removing parts of the protective layer to expose the parts of the copper layer underneath;
chemically removing the exposed parts of the copper layer to expose the parts of the dielectric layer underneath; and
removing the exposed parts of the dielectric layer to create the opening down to the top surface of the die contact pad.

15. A method according to claim 14, wherein removing parts of the protective layer to expose the parts of the copper layer underneath comprises:
exposing a light source to parts of the photoresist layer to alter the exposed parts of the photoresist layer; and
removing parts of the photoresist layer via the application of a developer to expose the parts of the copper layer underneath and, wherein chemically removing the exposed parts of the copper layer comprises:
applying a first chemical solution to the copper layer to expose the parts of the dielectric layer underneath, wherein the protective layer is unreactive to the first chemical solution.

16. A method according to claim 14, wherein removing the exposed parts of the dielectric layer comprises:
using a low-powered laser to cut through the exposed parts of the dielectric layer to create the opening down to the top surface of the die contact pad and, wherein removing the portion of the copper layer along with the portion of the dielectric layer to create the opening further comprises:
removing the remaining parts of the protective layer once the parts of the dielectric layer underneath are exposed or removing the remaining parts of the protective layer once the exposed parts of the copper layer are removed.

17. A method according to claim 16, wherein the remaining protective layer is chemically removed by the application of a second chemical solution, the copper layer being unreactive to the second chemical solution.

18. A method according to claim 1, wherein the one or more tracks are formed on a top surface of the dielectric layer and the one or more tracks comprise a third footprint in a plane defined by the top surface of the dielectric layer, wherein a surface area covered by the third footprint is larger than the surface area covered by the first footprint or the surface area covered by the second footprint.

19. A method according to claim 18, wherein the third footprint is geometrically similar to both the second footprint and the first footprint.

20. A method according to claim 1, wherein an embedded electronic device is manufactured.
